(19) United States
(12) Patent Application Publication
(10) Pub. No.: US 2019/0178844 A1
(43) Pub. Date: Jun. 13, 2019

(54) DIFFERENTIAL MAGNETIC EVALUATION FOR PIPELINE INSPECTION

(71) Applicant: Exxam Systems, LLC, Anchorage, AK (US)

(72) Inventors: Paul Lott, Anchorage, AK (US); Yuan Ji, Ames, IA (US)

(21) Appl. No.: 16/215,575

(22) Filed: Dec. 10, 2018

Related U.S. Application Data
(60) Provisional application No. 62/596,731, filed on Dec. 8, 2017.

(51) Int. Cl. G01N 27/90; G01M 3/40; G01R 33/028

(52) U.S. Cl. CPC G01N 27/9073; G01R 33/028; G01M 3/40

(57) ABSTRACT

A system and methods for inspecting a section of pipe are disclosed. The system includes two excitation coils disposed circumferentially around the section of pipe and a ring of magnetometer pairs arranged around the pipe between the two excitation coils. Each excitation coil is energized by an alternating current received from a power source and the energized excitation coils generate magnetic fields within the section of pipe. Each magnetometer pair includes two sensors that detect the strengths of the two magnetic fields. The system detects the presence of defects within the section of pipe by comparing the strengths of the magnetic fields measured by the two sensors within each magnetometer pair in the ring of magnetometer pairs.

### CROSS-REFERENCE TO RELATED APPLICATION(S)

This application claims the benefit of U.S. Provisional Application No. 62/596,731 filed on Dec. 8, 2017, entitled DIFFERENTIAL MAGNETIC EVALUATION FOR PIPELINE INSPECTION, which is incorporated herein by reference in its entirety.

### BACKGROUND

Inspection of various piping systems and pipelines for defects, cracks, corrosion, wear and the like is important for maintaining the integrity of such systems to avoid potentially catastrophic consequences from failure of pipes during use. In some applications, the piping systems are used to transport hot and/or corrosive materials. Often, such piping systems are provided with an exterior layer of insulation or the like, which prevents visual inspection of the piping system and inhibits the use of conventional inspection systems that require direct access to pipes. For example, piping systems for transporting petroleum products or the like over large distances often include a thick layer of polymeric insulation and an outer metal sheathing. Such piping systems are extremely difficult and costly to effectively monitor for wear, corrosion, damage and similar defects. Other piping systems are difficult to access for other reasons. For example, piping systems and risers associated with off-shore drilling are substantially located underwater, and are therefore difficult to access. Such piping systems may also be coated or encased with a protective outer casing, for example a plastic, elastomeric or metal outer jacket.

Conventional state of the art pipe inspection systems typically use inspection probes called inline inspection pigs that are inserted directly into the pipe and travel along the pipe. An inspection pig may be self-propelled or may be carried through the pipe by the flow within the pipe. One obvious disadvantage of inspection pigs is that they require access to the interior of a pipe. For many pipe systems, accessing the pipe to insert the inspection pig can be problematic, as it typically requires shutting down the flow within the pipe, significant internal cleaning and some disassembly and/or use of an access port. Furthermore, many pipe systems operate at high internal pressure in order to quickly move material through the pipes. Inserting or removing an inspection pig from a pressurized piping system can be dangerous and can lead to fatal accidents if care is not taken. It would therefore be desirable to provide a pipe inspection system that may be used for inspecting the condition of the pipe even when the pipe is not easily accessible, is in use, and/or is covered with a protective covering.

### BRIEF DESCRIPTION OF THE DRAWINGS

FIG. 1 is a perspective view of a pipe inspection system arranged around a pipe.

FIG. 2 is a cross-sectional diagram of the pipeline inspection system arranged around the pipe.

FIG. 3 is a diagram that shows a magnetometer sensor pair positioned over a pipe that includes a defect.

FIG. 4a is a perspective view of the pipe inspection system arranged around a portion of the pipe.

FIG. 4b is a perspective view of the pipe inspection system without a cover to expose the magnetometer pairs arranged on a surface of the magnetometer ring.

FIG. 4c is an isometric cross-sectional view of the magnetometer ring that shows the magnetometer pairs distributed around the magnetometer ring.

FIG. 5 is a flow chart of a method of using the pipe inspection system to detect defects in the pipe.

### DETAILED DESCRIPTION

An externally applied inspection system and method for non-invasive testing of piping or pipelines to detect the presence of defects is disclosed herein. The system includes a magnetometer ring with a plurality of magnetometer pairs that are circumferentially spaced about the magnetometer ring. Two excitation coils surround the pipe, and are mounted on either side of the magnetometer ring. Electric field generated in the excitation coils induce a magnetic field in the metal portions of a pipe being tested. The magnetic field is detected and measured by magnetometer pairs on the magnetometer ring. Each magnetometer pair includes two sensors that detect the strengths of the two magnetic fields. The system detects the presence of defects within the section of pipe by comparing the strengths of the magnetic fields measured by the two sensors within each magnetometer pair in the ring of magnetometer pairs

Various embodiments of the invention will now be described. The following description provides specific details for a thorough understanding and an enabling description of these embodiments. One skilled in the art will understand, however, that the invention may be practiced without many of these details. Additionally, some well-known structures or functions may not be shown or described in detail, so as to avoid unnecessarily obscuring the relevant description of the various embodiments. The terminology used in the description presented below is intended to be interpreted in its broadest reasonable manner, even though it is being used in conjunction with a detailed description of certain specific embodiments of the invention.

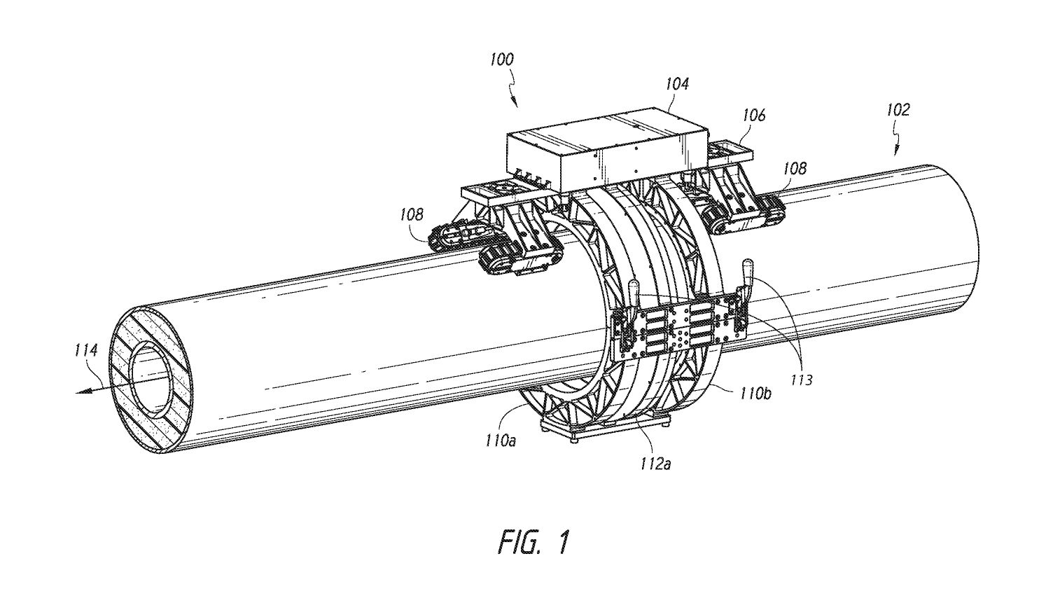

FIG. 1 depicts a perspective view of an inspection system 100 (the “system”) that is mounted to a pipe 102. The inspection system 100 includes first and second excitation coils 110a and 110b that wrap around the outer surface of pipe 102. A magnetometer ring 112 is disposed between the first and second excitation coils 110a and 110b. A transportation assembly 106, which includes multiple drive units 108 having rotating propulsion tracks, is mounted to excitation coils 110a, 110b and the magnetometer ring 112. The transportation assembly provides motive force to move the inspection system along pipe sections. System 100 also includes a controller 104, which provides control signals to the coils 110a, 110b, and the transportation assembly 106 and receives data from the magnetometer ring 112. As will be described in additional detail herein, signals applied to the excitation coil induce a magnetic field in the metal portions of pipe, which is detected and measured by the magnetometer ring.

The first and second excitation coils 110a and 110b are positioned around the exterior surface of pipe 102 at first and second axial positions, respectively. For convenience, the excitation coils 110a and 110b may each be formed from two semicircular halves that are configured to surround half of pipe 102. The two semicircular halves may be attached to each other at the ends of the halves using a clamp or clamps 113. The clamp (or clamps) 113 securely fasten the two halves of a given excitation coil to each other. However, the configuration depicted in FIG. 1 is merely an example. In some embodiments, the two halves of a given excitation coil 110a and 110b may be connected to each other with a movable hinge on one end and a clamp (or clamps) on the other end, allowing the two halves of the given excitation coil to remain attached to each other when system 100 is being attached to pipe 102. Each excitation coil 110a, 110b includes loops of conductive material, such as a copper wire, used to carry an electric current. The conductive material in each half of a given excitation coil may be connected to the conductive material in the other half with an electrical connector that is releasably engageable such that each coil 110a, 110b may be opened when inspection system 100 is attached to pipe 102. When attached to the pipe, the electrical connector ensures that the coil halves are connected and current can flow the coil.

Controller 104 includes an alternating current (AC) power supply (not shown) that is connected to the first and second excitation coils 110a and 110b, providing an alternating current to the two excitation coils in order to energize them. In some embodiments, the alternating current has a low frequency, such as a frequency less than 100 Hz, less than 10 Hz, or even less than 5 Hz. However, the optimal frequency range will depend on the particular geometry of the piping to be examined and one of ordinary skill in the art will be sufficiently able to identify a suitable frequency for a given piping section configuration. Additional frequencies and frequency patterns are disclosed in U.S. application Ser. No. 14/878,736, filed Oct. 8, 2015, entitled “EDDY CURRENT PIPELINE INSPECTION APPARATUS AND METHOD,” which is hereby incorporated by reference in its entirety.

Magnetometer ring 112 is arranged around the exterior surface of pipe 102 at a third axial position that is located between the first and second axial positions. The magnetometer ring may be located at a midpoint between the first and second excitation coils such that the distance between the third axial location and the first axial location is the same as the distance between the third axial location and the second axial location. The magnetometer ring 112 includes a plurality of magnetometer pairs (not shown) that are circumferentially spaced about the magnetometer ring 112 approximately adjacent to the exterior surface of the pipe 102. The magnetometer ring 112 may also be formed from two semicircular halves that are attached to each other with a hinge, allowing the magnetometer ring to open when being placed around the pipe 102. The use of a magnetometer ring with an inner circular opening ensures that the spacing and position of magnetometer pairs is accurately maintained. That is, a magnetometer pair may be spaced equidistance from the two neighboring magnetometer pairs based on the mounting location of the magnetometer pairs to the magnetometer ring. Moreover, each magnetometer pair may be accurately positioned adjacent to the exterior surface of the pipe 102 when the magnetometer ring is installed around the pipe. One or more clamps may also be used to secure the two semicircular halves of the magnetometer ring 112 to each other and electrical connectors may also be used to electrically connect circuitry in the two halves. As will be discussed in greater detail below, the electric field generated in the excitation coils 110a and 110b by the AC power induce a magnetic field in the metal portions of pipe 102, which is detected and measured by the magnetometer pairs.

Controller 104 can function as a data acquisition and processing system for receiving and processing data. The controller 104 includes a data acquisition system that is operatively connected to the magnetometer pairs and the AC power supply. The data acquisition system monitors the application of the AC power to the first and second excitation coils 110a and 110b by the AC power supply, which stimulates the generation of magnetic fields in the pipe being tested. The data acquisition system also receives sensor data from the magnetometer pairs, which is used to evaluate and inspect the pipe 102 in the vicinity of the magnetometer pairs. The data acquisition system may include analog-to-digital converters to convert measured analog signals from the magnetometer pairs into digital representations of those signals for further processing. In some embodiments, the controller 104 may include a data processing system that is used to pre-process the sensor data. The data processing system may include one or more microprocessors, microcontrollers, field programmable gate arrays (FPGAs) and memory. Signals from the magnetometer pairs may be digitized, stored, and then processed to filter the signals (e.g., to remove noise), to add or subtract different signals from each other, or to compare signal values to one or more thresholds. The controller 104 may be operatively connected to a remote data processing system (e.g., a laptop) using either a wired or a wireless connection. After pre-processing the sensor data, controller 104 may transmit the processed sensor data to the remote data processing system for further processing. In other embodiments, the controller 104 may not include a data processing system and may transmit the sensor data to the remote data processing system without the controller 104 performing any pre-processing.

Controller 104 may also include a tracking system (not shown) that is used to sense the position and/or movement of the system 100 as the system moves along the length of the pipe 102. In some embodiments, the tracking system may be a GPS module that may be used to collect position data of the system 100. The tracking system may also include accelerometers to measure the motion and speed of system 100 as it moves along pipe 102. The tracking system may also be configured to detect indicators attached to pipe 102 that can then be used to determine the location of the system 100, as well as the time at which system 100 passes by the indicators. The position data may be stored on controller 104 or may be transmitted to a remote monitoring system to enable real-time tracking of system 100.

Inspection system 100 may also include a transportation assembly 106 that is used to move inspection system 100 along the length of pipe 102. Transportation assembly 106 includes moving means, such as multiple drive units 108 with rotating tracks or treads that contact the exterior surface of pipe 102 and propel the inspection system along the pipe 102. As the transportation assembly moves the inspection system 100 along the length of the pipe 102, the system 100 may pause at regular intervals to inspect specific parts of pipe 102 using excitation coils 110a, 110b and the magnetometers in magnetometer ring 112. In other embodiments, the inspection may continuously move and inspect parts of pipe 102 using the excitation coils 110a, 110b and the magnetometers in the magnetometer ring without pausing at regular intervals. As the sensor data is collected with the magnetometers in magnetometer ring 112, the sensor data is correlated with position data from the tracking system. By correlating the position data with the magnetometer data collected at each inspection point, a user of the inspection system 100 is able to accurately determine the location and position of a defect in pipe 102.

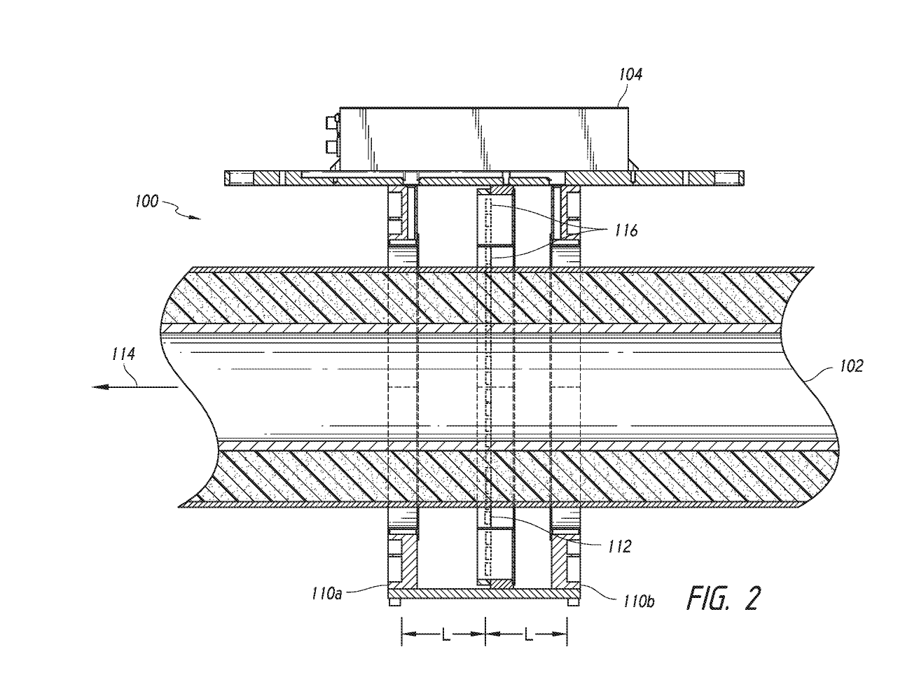

FIG. 2 is a diagram that shows a cross section of inspection system 100 that is arranged around pipe 102. Magnetometer ring 112, which includes a plurality of magnetometers pairs 116 circumferentially spaced around ring 112, is located between first and second excitation coils 110a and 110b, spaced an axial distance L away from both excitation coils. The excitation coils are connected to an AC power supply (not shown) in the controller 104. The AC power supply produces a first alternating current that is used to energize the first excitation coil 110a and a second alternating current that is used to energize the second excitation coil 110b. In some embodiments, the first and second alternating currents are in phase with each other. If desired, the AC power supply may generate a single alternating current that is applied to both the first and second excitation coils such that the alternating currents are in phase with each other. In other embodiments, the AC power supply may generate a single alternating current, but the current is split and phase-shifted before being applied to the first and second excitation coils 110a, 110b such that the alternating currents received by first and second excitation coils are out of phase with each other. In alternative embodiments, the AC power supply may separately generate first and second alternating currents that are provided to the first and second excitation coils 110a, 110b, respectively. These first and second alternating currents may be in phase or may be out of phase with each other.

During operation of the inspection system, excitation coils 110a and 110b are energized with an alternating current. Each excitation coil includes several loops of a conductive material, such as a copper wire, that receive the alternating current. As is well-known in the art, running a current through a wire generates a magnetic field around that wire. When an excitation coil is energized by an alternating current, it generates a magnetic field having a magnitude and direction that are dependent on the amount of current and the polarity of the alternating current passing through the excitation coil. The generated magnetic field propagates through pipe 102, producing localized magnetization in the metal portions of the pipe 102. The behavior of the magnetic field as it propagates through a conductive material is related to the physical properties of the material. For a material without any significant defects, such as cracks, corrosion, or pitting, the magnetic field propagates through the metal in a predictable manner, decreasing in magnitude as it moves further from the source of the magnetic field. However the magnetic field may deflect off of defects in the pipe, causing abnormalities in the propagation of the field. This phenomenon is often referred to as magnetic flux leakage because the magnetic field “leaks” from the conductive material. As the magnetic field propagates through the pipe 102, magnetometers placed on (or near) the surface of pipe 102 can detect and measure the magnitude of the magnetic field in order to detect defects in the pipe.

The measured magnitude of the magnetic field generated by an excitation coil 110 at a given point on pipe 102 is dependent on the distance between the magnetometer and the excitation coil and the strength of the current flowing through the wires in the excitation coil. Increasing the distance between the given magnetometer and the excitation coil and/or decreasing the strength of the current decreases the magnitude of the magnetic field measured by the magnetometer. Conversely, decreasing the distance between the magnetometer and the excitation coil and/or increasing the strength of the current increases the magnitude of the magnetic field measured by the magnetometer. The measured direction of the magnetic field is dependent on the polarity of the electric current that is applied to the excitation coil. If the electric field has a positive polarity, the magnetic field points in one direction. If the electric field has a negative polarity, the magnetic field points in the opposite direction. For magnetic fields generated by alternating currents, the direction the magnetic field points will thereby switch directions as the alternating current changes polarity.

Depending on the alternating current applied to the two excitation coils, there are different locations in the pipe being tested where constructive and destructive interference occurs between the stimulated magnetic fields. If the two magnetic fields are in phase with each other, the magnetic fields may constructively interfere and the measured magnitude at a given point is equal to the sum of the magnitudes of the two fields at that point. If the two fields are out of phase with each other, the two magnetic fields may destructively interfere and the measured magnitude at a given point is equal to the difference between the magnitudes of the two fields at that point. In other words, if two magnetic fields have the same magnitude at a given point and are in phase with each other, the measured magnitude at that given point will be equal to twice the magnitude of one of the magnetic fields. However, if the two magnetic fields have the same magnitude at a given point but are 180° out of phase, the measured magnitude at that given point will be zero, as the two magnetic fields will destructively interfere and cancel each other out at that point.

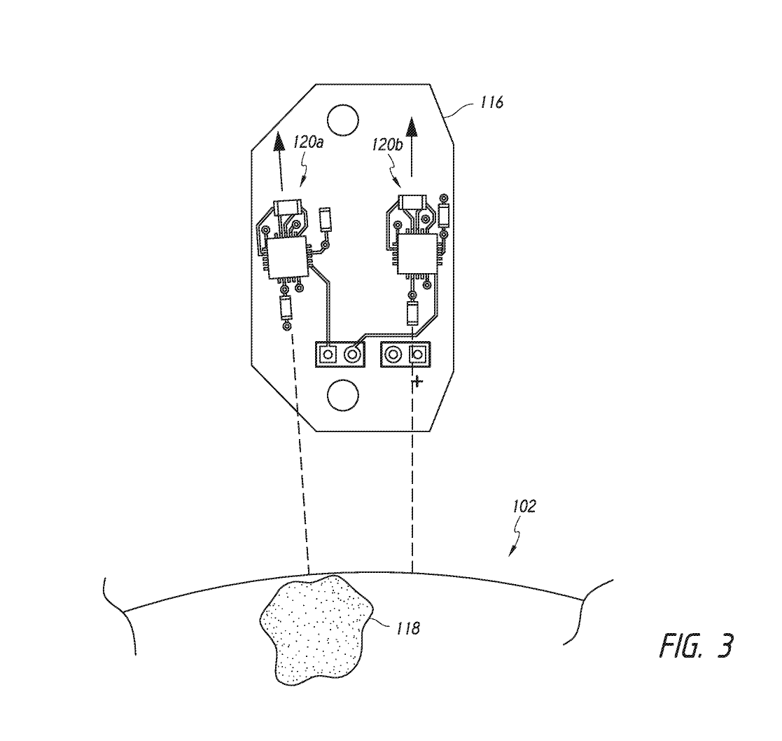

FIG. 3 is a representative diagram that shows a magnetometer pair 116 positioned over a defect 118 formed in the pipe 102. Magnetometer pair 116 includes a first magnetometer sensor (“sensor”) 120a and a second magnetometer sensor 120b that are able to detect and measure the strength of a magnetic field. Sensors 120a and 120b are radially positioned over respective first and second points on pipe 102 and are configured to measure the strength of the magnetic field at the first and second points. The sensors 120a and 120b in a given magnetometer pair 116 may be formed on a single circuit board and may be positioned at the same axial location around the pipe 102 (i.e., the magnetometer pairs are separated from one another in a radial direction around the pipe). The first and second magnetometer sensors 120a and 120b generate respective first and second sensor data based on the magnitude of measured magnetic fields in the pipe. The first and second sensor data from each magnetometer pair 116 is provided to the controller 104, which calculates a difference between the first and second sensor data for each magnetometer pair 116. When the magnetometer ring 112 is arranged around a portion of pipe 102 that has no defects (i.e., no cracks, corrosion, or pitting), the calculated difference between the first and second sensor data from a given magnetometer pair 116 will be low, indicating that the magnetic field measured by the first sensor 120a has a similar magnitude to the magnetic field measured by second sensor 120b.

However, when the magnetometer pair 116 is located over a portion of the pipe 102 that does have defects, the calculated difference between the first and second sensor data for a given magnetometer pair 116 will be higher, indicating that the magnetic fields measured by the first sensor 120a has a different magnitude than the magnetic field measured by the second sensor 120b. As previously mentioned, when a magnetic field interacts with a defect 118 in pipe 102, the magnetic field is disturbed by the pipe defect. When a magnetometer sensor is positioned above (or near) the defect, the change in the magnetic field caused by the magnetic flux leakage is detectable by the sensor. If a given magnetometer pair 116 is arranged near (or at least partially overlaps with) a portion of the pipe 102 that has a defect, one sensor 120a in the magnetometer pair 116 may detect a magnetic field that is affected by the defect while the other sensor 120b may detect a magnetic field that is not affected by the defect. In this scenario, the sensor data generated by the two sensors 120a, 120b will be different and the controller 104 can calculate a difference between the two sensor data. If the calculated difference is higher than a threshold, the controller 104 interprets such difference as evidence that a defect is located near the magnetometer pair 116.

In some embodiments, first and second sensors 120a and 120b may be vector magnetometer sensors, and more particularly fluxgate magnetometer sensors. In other embodiments, other types of magnetic field detectors may alternatively be used. For example, in some embodiments, sensors 120a and 120b may be magnetoresistive magnetometer sensors (e.g., giant magnetoresistive or anisotropic magnetoresistive magnetometer sensors).

Magnetometer sensors may have a direction of sensitivity along which the sensor is most sensitive to a magnetic field. As shown by the dashed lines interposed between the sensors 120 and the pipe 102 in FIG. 3, the first and second sensors 120a and 120b may have directions of sensitivity that are oriented towards the pipe 102. Preferably, the first and second sensors 120a and 120b are aligned so that each magnetometer pair 116 has a direction of sensitivity that is oriented towards the central axis of the pipe 102. In other words, the first sensor 120a is most sensitive to changes in the magnetic field that occur between the first sensor 120a and the central axis of the pipe 102 and the second sensor 120b is most sensitive to changes in the magnetic field that occur between the second sensor 120b and the central axis of the pipe 102. Depending on the size of the pipe being tested, and the number of magnetometer pairs, that means that the first sensor and the second sensor are aligned at slight angles (i.e., not parallel) to one another.

In the example shown in FIG. 3, defect 118 is located between the first sensor 120a and the central axis of the pipe 102, and therefore lies in the direction of sensitivity of the first sensor 120a, but defect 118 is not located between the second sensor 120b and the central axis of the pipe 102, and therefore does not lie in the direction of sensitivity of the second sensor 120b. During operation of inspection system 100, magnetic fields induced in the pipe 102 may interact with defect 118, changing the magnitude and/or direction of the magnetic field. Because defect 118 lies in the direction of sensitivity of first sensor 120a but not in the direction of sensitivity of second sensor 120b, the first sensor 120a will be more likely to detect the presence of defect 118 (by the perturbation of the magnetic field by the defect) than the second sensor 120b. In this scenario, the sensor data generated by the first sensor 120a will differ from the sensor data generated by the second sensors 120b. By calculating the difference in generated signals and comparing that difference with certain detection thresholds, the controller 104 can determine that a defect is present at the specific axial and radial location under first and second sensors 120a and 120b.

First and second sensors 120a and 120b are arranged at the same axial location along the pipe 102 but are located at different radial positions around the pipe. In order to ensure that the respective directions of sensitivity for the two sensors are oriented towards the central axis of the pipe 102, the two sensors are rotated relative to each other. In particular, the first and second sensors 120a and 120b are preferably rotated relative to each other such that their respective directions of sensitivity intersect at the central axis of the pipe 102. The amount that the first and second sensors 120a and 120b in a given magnetometer pair 116 are rotated relative to each other is dependent on the number of sensor pairs mounted on the magnetometer ring 112 (impacting the distance between the two sensors 120a, 120b) and the size of the pipe that the inspection system 100 is designed to inspect (determining the distance between the central axis of the pipe and the magnetometer pair 116). In the embodiment shown in FIG. 3, the first and second sensors 120a and 120b are one of 48 designed for measuring signals from a 24-inch diameter pipe. In that configuration, the respective directions of sensor sensitivity, are rotated by about 4° relative to each other. However, this is only an example. In other embodiments, the two sensors may be rotated by less than 4°, between 4° and 10°, or by more than 10°. In alternative embodiments, the two sensors 120a, 120b may be rotated by some other amount to each other. For example, first and second sensors 120a and 120b may perfectly parallel to each other. In general, the first and second sensors 120a and 120b may be oriented by any desired amount relative to each other.

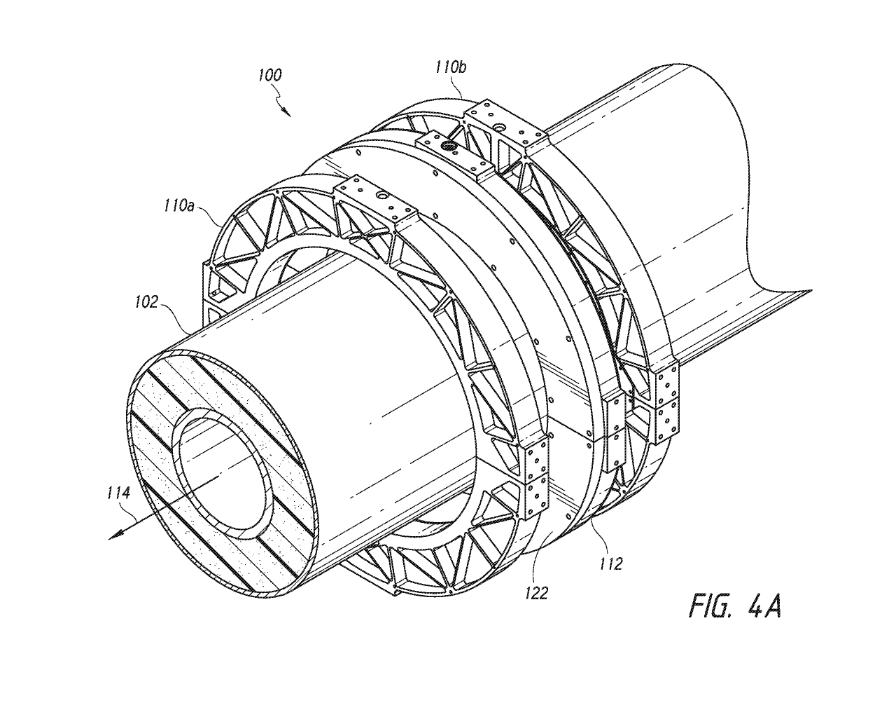

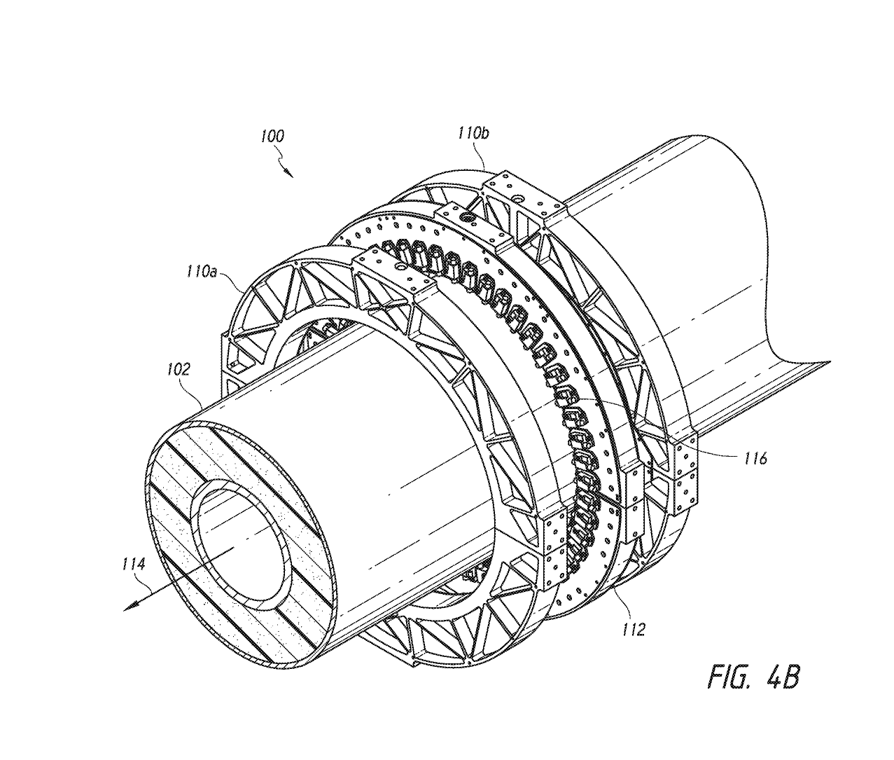

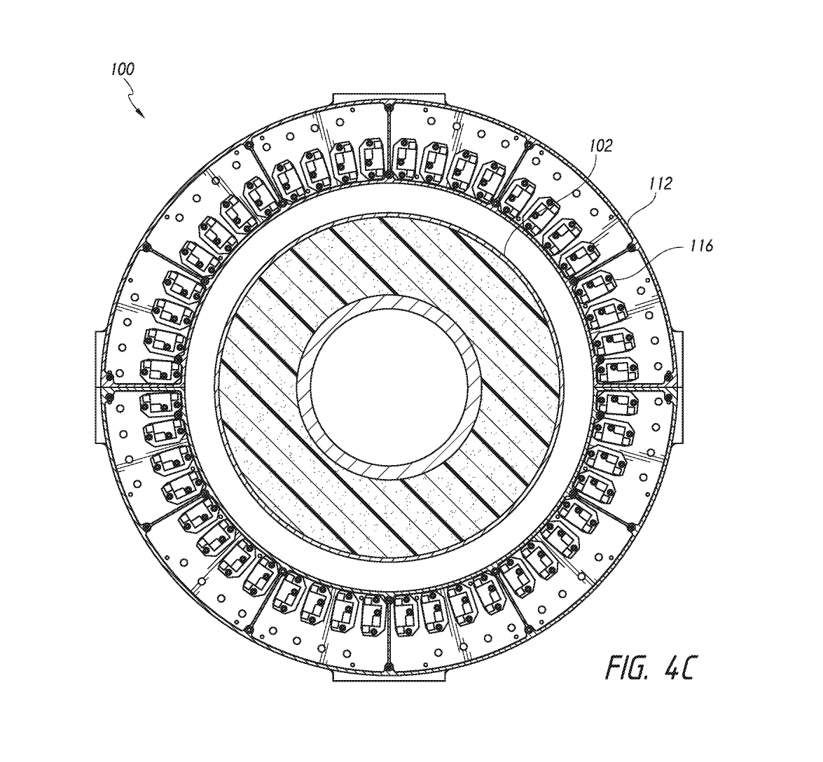

FIG. 4a is a perspective view of inspection system 100 positioned around a portion of pipe 112. Magnetometer ring 112 is arranged between first and second excitation coils 110a and 110b and encircles pipe 102. A cover 122 of the magnetometer ring 112 encloses the magnetometer pairs 116 and shields the magnetometer pairs from the external environment. FIG. 4b is a perspective view of inspection system 100 without cover 122, revealing the ring of magnetometer pairs 116 that are attached to the magnetometer ring 112. The magnetometer pairs 116 are arranged around the circumference of magnetometer ring 112. As shown in FIG. 4C, which is a perspective view of magnetometer ring 112, magnetometer ring 112 may include 48 magnetometer pairs 116 that are mounted on a surface of magnetometer ring 112 and arranged along an inner edge of the ring. Each magnetometer pair 116 includes first and second sensors, as previously described, and each magnetometer pair may be rotated by 7.5° relative to a neighboring magnetometer pair to ensure that each pair 116 is oriented towards the center of pipe 102. It will be appreciated that the depicted magnetometer ring 112 with 48 magnetometer pairs 116 is merely an example, and that the magnetometer ring may contain more or less pairs depending on the size of the pipe to be tested and the desired sensitivity. For example, magnetometer ring 112 may include less than 16, 16-24, less than 36, 36-60, or more than 60 magnetometer pairs 116. In general, magnetometer ring 112 may include any desired number of magnetometer pairs 116 that are arranged and evenly spaced around a surface of magnetometer ring 112. Each magnetometer pair 116 is typically rotated relative to the neighboring magnetometer pairs 116 to ensure that each magnetometer pair is oriented towards the center of pipe 102.

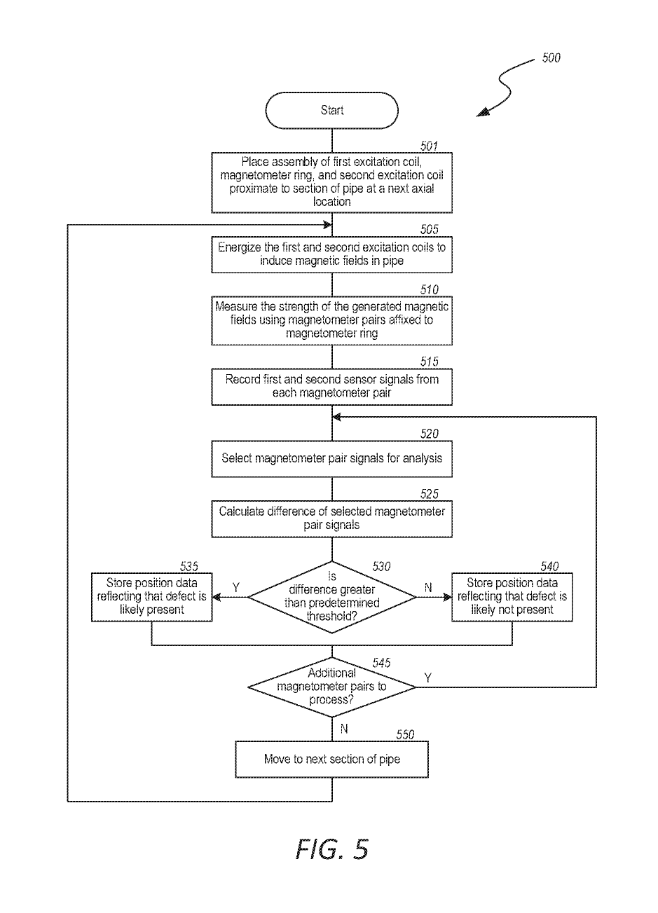

FIG. 5 is a flow chart of a method 500 of using inspection system 100 to detect a defect in a section of pipe. At step 501, the excitation coils and the magnetometer ring are placed around the exterior surface of a pipe under test. The first and second excitation coils are located proximate to a section of pipe at a first and second axial locations, and the magnetometer ring is located proximate the section of pipe at a third axial location that is at or near the midpoint of the distance between the first and second axial locations. The magnetometer ring may include any desired number of magnetometer pairs that are disposed around an interior surface of the magnetometer ring and are evenly spaced apart. In a preferred embodiment, the magnetometer ring may include 48 magnetometer pairs that each include a respective first and second sensors. As previously mentioned, the excitation coils and magnetometer ring may be releasably engageable around the exterior surface of the pipe using hinge and clamp mechanisms. In some alternative embodiments, the excitation coils may each be formed from two semi-circular halves that are separately arranged around the exterior surface of the pipe and clamping mechanisms are used to secure the two halves to each other.

At step 505, the first and second excitation coils are energized with an alternating current produced by a power source associated with the inspection system. The alternating current may have a frequency of less than 100 Hz, less than 10 Hz, or less than 5 Hz. The energized excitation coils induce an alternating magnetic field in the adjacent section of piping.

At step 510, the induced magnetic field is measured using the first and second sensors in the magnetometer pairs that are distributed around the magnetometer ring. The sensors are sensitive to the strength of the magnetic field at points in the pipe wall that are immediately adjacent to the sensors.

At step 515, the inspection system records first and second sensor signals from the first and second sensors in each magnetometer pair of the magnetometer ring. The signal values recorded by each magnetometer mounted on the magnetometer ring is stored in volatile or non-volatile memory of the inspection system for subsequent processing or review.

At step 520 the system selects a given one of magnetometer pairs in the magnetometer ring for analysis and at step 525 the system calculates a difference value for the selected magnetometer pair by determining the difference between the recorded first and second sensor signals of the pair. Because the first and second sensors in each magnetometer pair are disposed over the surface of the pipe at different radial locations, the magnetic field measured by the first and second sensors may be different, so the recorded sensor signals may also be different.

At step 530, the system compares the calculated difference value for the selected magnetometer pair to a predetermined threshold difference value and determines if the calculated difference is greater than the predetermined threshold. The predetermined threshold difference value is dependent on the size and composition of the pipe under analysis and is indicative of the presence of a defect. The threshold may be configured by a system operator when the inspection system is installed on the pipe or may be a dynamically determined by taking an average reading from all sensors on a pipe section with no known defects and applying a fixed percentage (e.g., 70%) to that average reading. If the calculated difference is greater than the predetermined threshold difference value, the method proceeds to step 535. If the calculated difference is less than or equal to the predetermined threshold difference value, the method proceeds to step 540.

At step 535, the system stores axial and radial position data of the selected magnetometer pair and indicates that a defect is likely present at the position. At step 540, the system stores axial and radial position data of the selected magnetometer and indicates that a defect is likely not present at the position. After storing the position data, the method proceeds to step 545.

At step 545, the system determines if there are additional magnetometer pairs that have yet to be analyzed at the axial location. If there are additional magnetometer pairs, the method returns back to step 520 to perform additional analysis of the remaining magnetometer pairs. If there are not any additional magnetometer pairs, the method proceeds to step 550.

At step 550, the system uses a transportation assembly to move the entire inspection system to a new section of the pipe. The inspection system is moved only so far as to ensure that all portions of underlying pipe are scanned by inspection system. After moving the inspection system, processing continues to step 505 and the inspection system scans the new section of pipe for the presence of defects.

As previously described, a power supply in controller 104 generates an alternating current with a low frequency. This alternating current, which has a frequency of less than 100 Hz, less than 10 Hz, or less than 5 Hz, generates a magnetic field in pipe 102 that interacts directly with defects in pipe 102. The direct interaction between the magnetic field and defects in the pipe 102 causes changes in the magnetic field due to magnetic flux leakage, which are detectable by sensors 120 in magnetometer ring 112. In other embodiments, the power supply in controller 104 may generate an alternating current with a frequency that is greater than or equal to 100 Hz, such as 150 Hz, 200 Hz, or 250 Hz. At these frequencies, sensors 120 may detect magnetic fields induced by eddy currents in pipe 102. Running an alternating current with a higher frequency through the excitation coils 110a, 110b induces a changing primary magnetic field disposed generally axially along the pipe 102. This primary magnetic field induces eddy currents within the pipe 102. Eddy currents then induce a secondary magnetic field that has an opposite direction from the primary magnetic field. The induced eddy currents within the pipe 102 will be impacted by defects or other anomalies in the pipe 102, such as cracks, corrosion, pitting, or the like. Changes in the eddy currents will in turn cause corresponding changes in the secondary magnetic fields induced by the eddy currents. The changes to the secondary magnetic fields are detectable by sensors 120.

In general, the source of the magnetic fields detected and measured by sensors 120 in magnetometer ring 112 is dependent on the frequency of the alternating current provided to the first and second excitation coils 110a and 110b. At lower frequencies, eddy currents generated by the magnetic field induced by excitation coils are not strong enough to generate secondary magnetic fields that are detectable by the sensors 120. At higher frequencies, the eddy currents generate secondary magnetic fields that overwhelm the effects of magnetic flux leakage on primary magnetic fields. At frequencies of about 100 Hz, sensors 120 in magnetometer ring 112 may detect defects in the pipe 102 due to the hybridized effects of magnetic flux leakage affecting primary magnetic fields in pipe 102 and secondary magnetic fields that are generated by eddy currents, which are affected by defects in the pipe 102.

The depth of the induced eddy currents in the pipe 102 is dependent on the frequency of the alternating current applied to the excitation coils 110a, 110b. For example, a higher frequency current applied to the excitation coils 110a, 110b may induce a relatively shallow eddy current (i.e., closer to the outer surface of the pipe 102). A lower frequency current applied to the excitation coils 110a, 110b may in turn induce a relatively deeper eddy current (i.e., closer to the inner surface of the pipe 102). The depth of the eddy current will depend on the characteristics of the AC signal applied to the excitation coil, the configuration of the coil, and the dimensions and materials of the pipe itself. By utilizing varying frequencies to produce eddy currents of varying depth, the depth of a defect can be detected in addition to detecting its axial location. For example, a scan including multiple frequencies applied sequentially can indicate both the axial location of the defect as well as the depth of the defect.

However, using multiple frequencies that are applied sequentially can be time-consuming. To expedite the process, a synthesized multi-frequency waveform can be applied to the excitation coils 110a, 110b in order to measure a range of depths simultaneously. For example, a multi-frequency waveform may include peaks at 100 Hz, 150 Hz, 200 Hz, and 250 Hz, which are each sensitive to defects at different depths of the pipe. The excitation coils generate four eddy currents in pipe 102, each corresponding to a specific frequency peak in the multi-frequency waveform of the primary magnetic field and each eddy current is only sensitive defects present at the same depth as the given eddy current. If a defect is located at a depth that corresponds to an eddy current induced by the 200 Hz peak of the multi-frequency waveform, as an example, then only the secondary magnetic field generated by the 200 Hz eddy current will be affected by the defect. Sensors 120 in magnetometer ring 112 may be able measure and detect both the frequency and the magnitude of the secondary magnetic field and sensor data that is transferred to controller 104 may include both frequency and magnitude data. By utilizing both the frequency data in conjunction with the magnitude data, the controller may be able to calculate the depth of a defect within the pipe, in addition to the axial and radial location of the defect.

As shown in FIG. 1, the inspection system 100 includes first and second excitation coils 110a and 110b. However, this is merely an example. In other embodiments, the inspection system 100 may include only a single excitation coil 110. During operation of the inspection system 100, a current may be generated by a power supply in controller 104. The current is provided to the single excitation coil 110, which generates a magnetic field in the pipe 102 using the provided current. Sensors 120 in magnetometer ring 112 detect and measure the magnetic field generated by the single excitation coil and provide sensor data to the controller 104 based on the strength of the magnetic field.

In some embodiments, magnetic fields in pipe 102 are induced by excitation coils 110a and 110b when a current is run through conductive material in the excitation coils 110a and 110b. In other embodiments, however, the magnetic fields may be induced in pipe 102 using other magnetic means. For example, in some embodiments, inspection system 100 may include permanent magnets, such as rare earth magnets, that are used to induce magnetic fields in pipe 102. In other embodiments, the power supply may generate a direct current that is provided to the excitation coils 110a, 110b instead of an alternating current to produce a static magnetic field. In general, the system 100 may induce a magnetic field in the pipe 102 using any desired mechanism.

From the foregoing, it will be appreciated that specific embodiments of the invention have been described herein for purposes of illustration, but that various modifications may be made without deviating from the scope of the invention. Accordingly, the invention is not limited except as by the appended claims.

I/We claim:

1. A system for inspecting a section of piping, the system comprising:
a power source;
an excitation coil disposed at a first axial location, wherein the excitation coil is energized by the power source;
a plurality of magnetometer pairs spaced equidistant around the perimeter of a magnetometer ring disposed at a second axial location adjacent to the first axial location, wherein each of the plurality of magnetometer pairs comprises a first magnetometer and a second magnetometer configured to detect magnetic fields induced in the section of piping by the first excitation coil;
a data acquisition and processing system operatively connected to receive output data from the plurality of magnetometer pairs, wherein the data acquisition and processing system is configured to calculate a difference between output data from the first and second magnetometers for each of the plurality of magnetometers.

2. The system of claim 1, wherein the power source is an alternating current power source.

3. The system of claim 2, wherein the alternating current power source energizes the excitation coil with a multi-frequency waveform.

4. The system of claim 1, wherein the excitation coil comprises a first excitation coil, the system further comprising:
a second excitation coil disposed at a third axial location, wherein the second axial location is between the first and third axial locations.

5. The system of claim 4, wherein the second axial location is separated from the first axial location by a given distance, and wherein the third axial location is separated from the second axial location by the given distance.

6. The system of claim 1, further comprising:
a plurality of circuit boards, wherein the first and second magnetometers for each of the plurality of magnetometer pairs is formed on a given one of the plurality of circuit boards.

7. The system of claim 6 wherein the first magnetometer for each of the plurality of magnetometer pairs has a first direction of sensitivity and the second magnetometer for each of the plurality of magnetometer pairs has a second direction of sensitivity that is different from the first direction of sensitivity.

8. The system of claim 6, wherein the first and second magnetometers in each of the plurality of magnetometer pairs are located at respective first second radial positions around the section of piping.

9. The system of claim 8, wherein the first and second magnetometers in each of the plurality of magnetometer pairs are aligned at an angle greater than 0°.

10. The system of claim 1, further comprising:
a transportation assembly that is configured to move the system along the section of piping; and
a tracking system that is configured to track the system as it moves along the section of piping.

11. A system for inspecting a section of piping, the system comprising:
a power source that generates first and second currents;
a first excitation coil disposed at a first axial location, wherein the first excitation coil is energized by the power source with the first current;
a second excitation coil disposed at a second axial location, wherein the second excitation coil is energized by the power source with the second current;
a plurality of magnetometer pairs disposed at a third axial location between the first axial location and the second axial location, wherein each magnetometer pair includes a first and a second magnetometer, wherein the magnetometer pairs are positioned to detect magnetic fields generated in the section of piping by the first and second excitation coils;
a data acquisition system operatively connected to receive output data from the plurality of magnetometer pairs; and
a data processing system, wherein the data processing system is configured to calculate a difference between output data from the first and second magnetometers for each of the plurality of magnetometer pairs.

12. The system of claim 11, wherein each magnetometer in the plurality of magnetometer pairs comprises a fluxgate magnetometer.

13. The system of claim 11, wherein the first current is the same as the second current.

14. The system of claim 11, wherein the first current is different than the second current.

15. The system of claim 11, wherein the third axial location is separated from the first axial location by a given distance and wherein the third axial location is separated from the second axial location by the given distance.

16. The system of claim 11, wherein the plurality of magnetometer pairs are evenly spaced around the circumference of the piping section at the third axial location.

17. The system of claim 16, wherein the respective first and second magnetometers in each magnetometer pair are located at a given axial position along the section of piping.

18. The system of claim 11, further comprising:
a transportation assembly that is configured to move the system along the section of piping; and
a tracking system that is configured to track the system as it moves along the section of piping.

19. A method for inspecting a section of a pipe, comprising:
placing a first excitation coil proximate the section at a first axial location;
placing a second excitation coil proximate the section at a second axial location that is axially spaced apart from the first axial location;
placing a plurality of magnetometer pairs proximate the section at a third axial location between the first axial location and the second axial location, wherein individual of the plurality of magnetometer pairs is oriented toward the pipe;
energizing the first and second excitation coils with a power source;
recording a plurality of signals from the plurality of magnetometer pairs to a data acquisition unit, where each magnetometer pair outputs a first signal and a second signal and wherein the plurality of signals comprises the first and second signals from each magnetometer pair;
determining a plurality of difference values by comparing the respective first and second signals from each magnetometer pair in the plurality of magnetometer pairs; and
determining, based at least partly on the plurality of difference values, if a defect is located near a given magnetometer pair by comparing each of the plurality of difference values to a predetermined threshold value.

20. The method defined in claim 19, wherein determining the location of the defect in the pipe comprises determining an axial location of the defect.

21. The method defined in claim 19, wherein determining the location of the defect in the pipe comprises determining a radial location of the defect.

22. The method defined in claim 19, wherein each pair of magnetometers in the plurality of magnetometer pairs comprises a first and a second magnetometer, wherein the first magnetometer in a given pair outputs the respective first signal and the second magnetometer in the given pair outputs the respective second signal, and wherein comparing the first and second signals comprises subtracting the first signal from the second signal.

23. The method defined in claim 19, wherein each magnetometer in the plurality of magnetometer pairs is a fluxgate magnetometer.

24. The method of claim 19, wherein the section of the pipe comprises a first section of the pipe and the plurality of signals comprises a first plurality of signals, the method further comprising:
moving the first excitation coil, the second excitation coil, and the plurality of magnetometer pairs to a second section of the pipe; and
monitoring the plurality of magnetometer pairs to receive a second plurality of signals that is different from the first plurality of signals.
